(19) United States
(12) Patent Application Publication
(10) Pub. No.: US 2025/0028879 A1
(43) Pub. Date: Jan. 23, 2025

(54) SYSTEMS AND METHODS FOR FORECASTING DATA DRIFT FOR MODEL MONITORING

(71) Applicant: Capital One Services, LLC, McLean, VA (US)

(72) Inventors: Brian BARR, Schenectady, NY (US); Jeremy GOODSITT, Champaign, IL (US)

(73) Assignee: Capital One Services, LLC, McLean, VA (US)

(21) Appl. No.: 18/355,391

(22) Filed: Jul. 19, 2023

(51) Int. Cl. G06F 30/27

(52) U.S. Cl. CPC G06F 30/27

(57) ABSTRACT

Systems and methods for forecasting data drift for model monitoring. In some aspects, the system receives a current explainability vector for a machine learning model and a data drift vector for historical data profiles. The machine learning model is trained on historical data including values for a first set of features. The system generates a projected synthetic dataset using the data drift vector and updates the machine learning model based on the projected synthetic dataset. Using the current explainability vector and a future explainability vector for the updated model, the system generates a second set of features and determines a drift threshold vector for the second set of features based on values in the explainability vectors. The system determines a discrepancy score for each feature of the second set of features. The system generates an alert including features in the second set of features and their associated discrepancy scores.

### SUMMARY

Data drift within training data presents a challenge for training machine learning models. Data drift can describe changes to distributions or characteristics of data along one or more features over time. Data drift is challenging to machine learning because the training data and underlying statistical distributions for a model at the time of training being poorly matched to statistical distributions under real circumstances causes the model to perform poorly in its predictions. Early diagnosis and prompt tuning of the model can help mitigate effects of data drift in training data used for training or updating the model.

Methods and systems are described herein for novel uses and/or improvements to artificial intelligence applications and in particular to forecasting data drift for model monitoring. To address these data quality problems, methods and system herein use historical data profiles, synthetic projected data, and explainable artificial intelligence techniques to select pertinent features and detect data drift. Doing so can pre-empt impact of changes to training data used for training or updating models, giving engineers sufficient time to re-select algorithms or to retrain model parameters in a timely fashion.

Existing systems lack a comprehensive framework for identifying features for which to detect data drift. In complex models, input features may be myriad, and anticipating degrees of drift for all features is impractical. Conventional systems have not contemplated using explainability techniques to select features important to the model at a current time or in the future. Conventional systems also have not contemplated using synthetic data that captures expected changes to training data to re-train models prior to said changes in anticipation of data drift. Furthermore, conventional systems have not contemplated adjusting the sensitivity thresholds for data drift based on the importance of each feature. By contrast, the systems and methods disclosed herein use historical data profiles to generate synthetic projected data, with which the model can be retrained or updated. Using the baseline model and the updated model, the system may select features for importance, set thresholds for excessive data drift based on importance, and generate notifications that reflect any issues.

In some aspects, a method for using historical data profiles, projected synthetic datasets, and explainable artificial intelligence techniques to forecast data drift for model monitoring is disclosed, comprising: receiving a current explainability vector for a machine learning model and a data drift vector for a plurality of historical data profiles, wherein the machine learning model is trained on historical data, wherein the historical data profiles correspond to instances of the historical data at different times, and wherein the historical data comprises values for a first set of features; using the data drift vector, generating a projected synthetic dataset, wherein the projected synthetic dataset comprises values for the first set of features at a future time; updating the machine learning model based on the projected synthetic dataset to generate an updated machine learning model; using the current explainability vector and a future explainability vector for the updated machine learning model, generating a second set of features, wherein the second set of features is a subset of the first set of features; determining a drift threshold vector for the second set of features based on an associated value for each feature in the current explainability vector and the future explainability vector; based on an associated entry in the drift threshold vector and the data drift vector, for each feature of the second set of features, determining a discrepancy score between the associated entry in the drift threshold vector and an associated entry in the data drift vector; and generating an alert including one or more features in the second set of features and their associated discrepancy scores.

Various other aspects, features, and advantages of the systems and methods described herein will be apparent through the detailed description and the drawings attached hereto. It is also to be understood that both the foregoing general description and the following detailed description are examples and are not restrictive of the scope of the systems and methods described herein. As used in the specification and in the claims, the singular forms of “a,” “an,” and “the” include plural referents unless the context clearly dictates otherwise. In addition, as used in the specification and the claims, the term “or” means “and/or” unless the context clearly dictates otherwise. Additionally, as used in the specification, “a portion” refers to a part of, or the entirety of (i.e., the entire portion), a given item (e.g., data) unless the context clearly dictates otherwise.

### BRIEF DESCRIPTION OF THE DRAWINGS

FIG. 1 shows an illustrative diagram for a system for forecasting data drift for model monitoring, in accordance with one or more embodiments.

FIG. 2 show an illustration of a first set of features and a second set of features in a real-valued space, in accordance with one or more embodiments.

FIG. 3 shows illustrative components for a system for forecasting data drift for model monitoring, in accordance with one or more embodiments.

FIG. 4 shows a flowchart of the steps involved in forecasting data drift for model monitoring using topological data analysis, in accordance with one or more embodiments.

### DETAILED DESCRIPTION

In the following description, for the purposes of explanation, numerous specific details are set forth in order to provide a thorough understanding of the embodiments described herein. It will be appreciated, however, by those having skill in the art that the embodiments may be practiced without these specific details or with an equivalent arrangement. In other cases, well-known structures and devices are shown in block diagram form in order to avoid unnecessarily obscuring the embodiments.

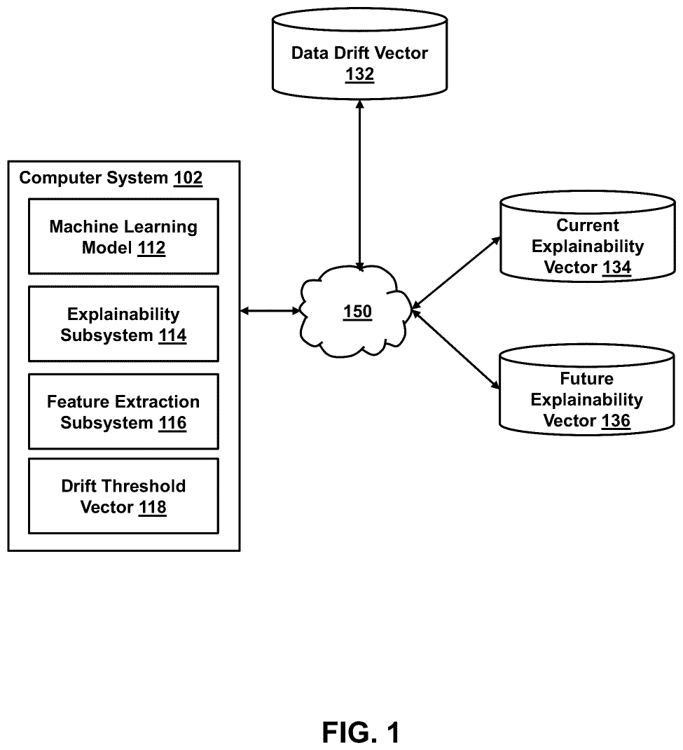

FIG. 1 shows an illustrative diagram for system 150, which contains hardware and software components used for detecting anomalous data updates, in accordance with one or more embodiments. For example, Computer System 102, a part of system 150, may include Machine Learning Model 112, Explainability Subsystem 114, Feature Extraction Subsystem 116, and Drift Threshold Vector 118. Additionally, system 150 may create, store, and use Data Drift Vector 132, Current Explainability Vector 134, and Future Explainability Vector 136 in one or more contexts.

The system (e.g., system 150) may train Machine Learning Model 112 using historical data. The historical data may include a first set of features, some or all of which may be used as input features in Machine Learning Model 112. The system may receive historical data from one or more data sources, client devices, or databases over a period of time preceding the training of Machine Learning Model 112. The historical data may, for example, correspond to observations in the real world and may be collected by one or more data collection protocols. The historical data may be collected for the purpose of training a machine learning model to perform a particular task.

The first set of features may contain categorical or quantitative variables, and values for such features may describe, for example for models predicting resource availability values, the user system's make and model, the user system's location, the membership of the user system in any networks, any allocations of resources to the user system, a length of time for which the user system has recorded resource consumption, an extent and frequency of resource consumption, and the number of instances of the user system's excessive resource consumption. A vector of values for the first set of features corresponding to a user system may be referred to as a user profile. In some embodiments, historical data may include one or more user profiles. In addition to datasets of user profiles, historical data may include other types of data. Each user profile may correspond to a resource availability value indicating the current amount of resources that should be made available to or reserved for the user system, which may also be recorded in the historical data in association with the user profile. The system may retrieve a plurality of user profiles as a matrix including vectors of feature values for the first set of features and append to the end of each vector a resource consumption value.

In some embodiments, the system may, after retrieving the historical data, process it using a data cleansing process to generate a processed dataset. The data cleansing process may include standardizing data types, formatting and units of measurement, and removing duplicate data. The system may then retrieve vectors corresponding to user profiles from the processed dataset.

In some embodiments, the historical data may correspond to a plurality of historical data profiles generated from the historical data. A historical data profile may be a descriptive summary of one or more aspects of historical data at a point in time. Alternatively or additionally, data profiles may capture changes to historical data across time. A data profile describing a dataset within the historical data (e.g., including a first set of features) may include descriptive statistics regarding the dataset. For example, the data profile may include a vector of averages across the first set of features in the dataset. For example, the data profile may include distributions of the first set of features in the dataset. For example, the data profile may include a list of frequencies of null values for the first set of features. For example, the data profile may include a covariance matrix between the first set of features.

Machine Learning Model 112 may be trained on the historical data to perform prediction and/or classification using the first set of features as input. It may use algorithms such as neural networks, linear regression, Bayesian regression, and/or K-nearest neighbors to process the first set of features into an output. The system may partition the matrix of user profiles into a training set and a cross-validating set. Using the training set, the system may train Machine Learning Model 112 using, for example, the gradient descent technique. The system may then cross-validate the trained model using the cross-validating set and further fine-tune the parameters of the model. Machine Learning Model 112 may include one or more parameters that it uses to translate input into outputs. For example, an artificial neural network contains a matrix of weights, each weight in which is a real number. The repeated multiplication and combination of weights transform input values to Machine Learning Model 112 into output values.

The system may use Explainability Subsystem 114 to extract an explainability vector (e.g., Current Explainability Vector 134) from Machine Learning Model 112. Explainability Subsystem 114 may employ a variety of explainability techniques depending on the algorithms in Machine Learning Model 112 to extract Current Explainability Vector 134. Current Explainability Vector 134 contains one entry for each feature in the set of features in the input to Machine Learning Model 112, and the entry reflects the importance of that feature to the model. The values within Current Explainability Vector 134 additionally represent how each feature correlates to the output of the model, and the causative effect of each feature in producing the output as construed by the model. In some embodiments, a correlation matrix may be attached to Current Explainability Vector 134. The correlation matrix captures how variables are correlated with other variables. This is relevant because correlation between variables in a model causes interference in their causative effects in producing the output of the model.

Below are some examples of how Explainability Subsystem 114 extracts Current Explainability Vector 134 from Machine Learning Model 112.

For example, Machine Learning Model 112 may contain a matrix of weights for a multivariate regression algorithm. Explainability Subsystem 114 may use a Shapley Additive Explanation method to extract Current Explainability Vector 134. Shapley Additive Explanation computes Shapley values in coalitional game theory, treating each feature in the input features of a model as participants in a coalition. Each feature therefore gets assigned a Shapley value capturing their contribution to producing the prediction of the model. The magnitude of Shapley values of each feature is then normalized. Current Explainability Vector 134 may be a list of normalized Shapley values of each feature.

In another example, Machine Learning Model 112 may contain a vector of coefficients for a generalized additive model. Since the nature of generalized additive models is such that the effect of each variable on the output is completely and independently captured by its coefficient, Explainability Subsystem 114 may take the list of coefficients to be Current Explainability Vector 134.

In another example, Machine Learning Model 112 may contain a matrix of weights for a supervised classifier algorithm. Explainability Subsystem 114 may use a Local Interpretable Model-agnostic Explanations method to extract Current Explainability Vector 134. The Local Interpretable Model-agnostic Explanations approximates the results of Machine Learning Model 112 with an explainable model, e.g., a decision tree classifier. The approximate model is trained using a loss heuristic that judges similarity to Machine Learning Model 112 and that penalizes complexity. In some embodiments, the number of variables that the approximate model uses can be specified. The approximate model will clearly define the effect of each feature on the output: for example, the approximate model may be a generalized additive model.

In another example, Machine Learning Model 112 may contain a matrix of weights for a convolutional neural network algorithm. Explainability Subsystem 114 may use a Gradient Class Activation Mapping method to extract Current Explainability Vector 134. The Grad-CAM technique performs backpropagation on the output of the model with respect to the final convolutional feature map to compute derivatives of features in the input with respect to the output of the model. The derivatives may then be used as indications of importance of features to a model, and Current Explainability Vector 134 may be a list of such derivatives.

In another example, Machine Learning Model 112 may contain a set of parameters comprising a hyperplane matrix for a support vector machine algorithm. Explainability Subsystem 114 may use a counterfactual explanation method to extract Current Explainability Vector 134. The counterfactual explanation method looks for input data which are identical or extremely close in values for all features except one. Then the difference in prediction results may divided by the difference in the divergent value. This process is repeated on each feature for all pairs of available input vectors, and the aggregated result is a measure for the effect of each feature on the output of the model, which may be formed into Current Explainability Vector 134.

After extracting Current Explainability Vector 134 from Machine Learning Model 112, the system (e.g., using Feature Extraction Subsystem 116) may process the explainability vector using one or more filtering criteria to adjust the values corresponding to certain features. In some embodiments, these adjustments may be performed in response to a user request. For example, the system may receive a user request specifying that a subset of features be removed from consideration or that impact of the subset of features be reduced. In one example embodiment, the system may receive user profiles representing applicants for credit cards. A feature in the set of features may be the race or ethnicity of the applicant. The user may wish to exclude such features from consideration. Therefore, a subset of features to be removed may include, e.g., race and gender. Feature Extraction Subsystem 116 may, in addition, calculate a threshold for removing features of the explainability vector. In some embodiments, the threshold may correspond to a pre-set real number, e.g., 0.45. In other embodiments, Feature Extraction Subsystem 116 may simply remove the bottom 10% of features ranked by values in the explainability vector. Using the threshold, Feature Extraction Subsystem 116 may add features to the subset of features to be removed. Feature Extraction Subsystem 116 may apply a mathematical transformation to the explainability vector such that values corresponding to the subset of features are adjusted. For example, the values in the explainability vector for the subset of features may be set to zero, or the values may be halved.

Based on the historical data and/or the historical data profiles, the system may generate a data drift vector (e.g., Data Drift Vector 132). In some embodiments, the system may process the historical data and/or its corresponding data profiles using an extrapolation model to generate a data drift vector. Data Drift Vector 132 may be a vector of real values, each value corresponding to a feature in the first set of features. Each value within Data Drift Vector 132 may indicate an expected change to the average of the feature. In some embodiments, the entries in Data Drift Vector 132 may correspond to features in data profiles. In some embodiments, the data drift vector may include an expectation value and a measure of variance. The expectation value may be a vector of real values corresponding to the first set of features and the plurality of data profiles. The measure of variance may be a vector of real values, where each value is derived from a standard deviation of a feature in the set of features. Therefore, Data Drift Vector 132 may capture the expected values and expected variances for some or all of the features in the first set of features independently.

To generate the expectation value and the measure of variance, the system may use extrapolation machine learning models. For example, a time-series extrapolation machine learning model may use algorithms like Bayesian regression, time-series regression and/or principal component analysis. The extrapolation machine learning models may take the historical data profiles as input and may output predicted values for a set of features, each predicted value corresponding to a range of error. Thus, the system may use the predicted values to generate Data Drift Vector 132 by comparing the predicted values against the historical data.

The system may generate a projected synthetic dataset using the data drift vector. For example, the system may use a first regression model to process the data drift vector and the historical data to generate projected values for the first set of features. In some embodiments, the data drift vector includes a set of values indicating projected expectations for the first set of features. In other embodiments, the system may calculate projected expectations for the first set of features using Data Drift Vector 132. For example, if Data Drift Vector 132 indicates an expected 10% in the mean of a feature and a 20% reduction in the variance of that feature, the system may generate projected expectations including expected mean values that are 0.9 times the current mean values, and expected variance that are 0.8 times the current variance. The system may generate the projected synthetic dataset using the projected expectations. For example, the system may simulate a statistical distribution with mean values equal to projected expectations and variance equal to projected variation. Using the statistical distribution, the system may generate values for the first set of features, which may be collected to form a projected synthetic dataset.

The system may update Machine Learning Model 112 based on the projected synthetic dataset. Machine Learning Model 112 may be retrained on the projected synthetic dataset to perform prediction and/or classification, again using the first set of features as input. It may use the same algorithms as before, such as neural networks, linear regression, Bayesian regression, and/or K-nearest neighbors, to process the first set of features into an output. The system may partition the projected synthetic dataset into a training set and a cross-validating set. Using the training set, the system may train Machine Learning Model 112 using, for example, the gradient descent technique. The system may then cross-validate the trained model using the cross-validating set and further fine-tune the parameters of the model. Despite using the same set of features, the updated model may have a different set of weights and other parameters than Machine Learning Model 112, because it was trained on the projected synthetic dataset. Consequently, the importance of each feature may be different from its importance in Machine Learning Model 112.

The system may then process the updated machine learning model to extract a future explainability vector (e.g., Future Explainability Vector 136). The system may again use Explainability Subsystem 114, which may employ a variety of explainability techniques depending on the algorithms in the updated model. Future Explainability Vector 136 contains one entry for each feature in the set of features in the input to the updated model, and the entry reflects the importance of that feature to the updated model. The values within Future Explainability Vector 136 additionally represent how each feature correlates to the output of the updated model, and the causative effect of each feature in producing the output as construed by the updated model. Future Explainability Vector 136 may be of the same format as Current Explainability Vector 134 described above.

The system may choose a second set of features based on Current Explainability Vector 134 and Future Explainability Vector 136. Feature Extraction Subsystem 116 may, for example, calculate a threshold for including features in the second set based on the explainability vector. In some embodiments, the threshold may correspond to a pre-set real number, e.g., 0.45. In other embodiments, Feature Extraction Subsystem 116 may simply select the top 10% of features ranked by values in the explainability vector. Using the threshold, Feature Extraction Subsystem 116 may add features to the second of features. In some embodiments Feature Extraction Subsystem 116 may combine features with reference to Current Explainability Vector 134. For example, it may select features with low values in Current Explainability Vector 134 and map one or more such features into one combined feature. Feature Extraction Subsystem 116 may, for example, multiply the absolute values for three features to generate one new feature. Alternatively, Feature Extraction Subsystem 116 may determine whether all three feature values exceed thresholds for each and create a new feature which outputs 1 if all values are above their respect thresholds, and outputs 0 otherwise.

In some embodiments, Feature Extraction Subsystem 116 may employ a variety of techniques to rearrange or recombine the first set of features into the second set of features. For example, Feature Extraction Subsystem 116 may normalize Current Explainability Vector 134 into a standard-deviation space to produce a processed vector. Then, with reference to the correlation matrix attached to Current Explainability Vector 134, Feature Extraction Subsystem 116 may generate a covariance matrix based on the processed vector. The covariance matrix captures how the effects on the output of the model of one or more features correlate. Using the covariance matrix, Feature Extraction Subsystem 116 may compute a set of eigenvectors and eigenvalues for the covariance matrix (e.g., through the Singular Value Decomposition method). Each eigenvector corresponds to an eigenvalue and represents a feature in the first set of features. The relative proportions of the eigenvalues are directly correlated with the magnitude of a factor's explanative weight in Machine Learning Model 112. By normalizing the eigenvalues of all features in the first set of features, the system may determine what percentage of the explanative power of the model may be captured by each feature. Feature Extraction Subsystem 116 may then select a measure of coverage (e.g., a threshold percentage of the explanative power of the model). Using the measure of coverage, Feature Extraction Subsystem 116 may select a subset of eigenvectors from the set of eigenvectors. For example, if the measure of coverage is 55%, and three eigenvectors' eigenvalues add up to 56% when normalized, Feature Extraction Subsystem 116 may select the three eigenvectors. Feature Extraction Subsystem 116 may then determine the second set of features to correspond to the subset of eigenvectors.

In some embodiments, after Feature Extraction Subsystem 116 has processed the covariance matrix (also referred to herein as a correlation matrix) to generate a set of eigenvectors, Feature Extraction Subsystem 116 may compute a distribution of eigenvalues corresponding to the set of eigenvectors. Using the distribution of eigenvalues, the system may set a threshold and use a maximum-likelihood estimator model to extract the second set of features.

The system may then determine a drift threshold vector (e.g., Drift Threshold Vector 118) for the second set of features. Drift Threshold Vector 118 may be inversely proportional to values in explainability vectors for each feature in the second set of features. For example, the system may initialize a uniform vector, where each value is the same real number. Then the system may calculate a weight vector, each value in which corresponds to a feature in the second set of features. For each feature in the second set of features, the feature has a value in Current Explainability Vector 134 and a value in Future Explainability Vector 136. The weight may be the higher of these two values. In some embodiments, the weight may be a mathematical combination of the two values, for example an average. The system determines values for Drift Threshold Vector 118 by dividing each value in the uniform vector by each value in the weight vector. The higher that a feature's values in Current Explainability Vector 134 and Future Explainability Vector 136 are, the lower its threshold in Drift Threshold Vector 118.

For each feature of the second set of features, the system may determine a discrepancy score using the drift threshold vector and the data drift vector for each feature in the second set of features. The data drift vector may indicate an expected change to the mean for a feature. In some embodiments, the expected changes to the mean may be normalized to be a standard-deviation space. In some embodiments, the uniform vector used in generating the drift threshold vector may be selected to be in the same order of magnitude as the data drift vector. The system may compare values in the data drift vector for the second set of features against values in the drift threshold vector. For example, the system may compute a numerical difference in the real number in the data drift vector and the drift threshold vector for each feature and set the value as the discrepancy score for that feature.

The system may generate an alert including one or more features in the second set of features and their associated discrepancy scores. For example, some features in the second set of features may have positive discrepancy scores, indicating that the degree of drift exceeded the drift threshold for that feature. The system may select those features, and generate an alert (e.g., in an alert dashboard displayed to users) indicating those features and their discrepancy scores. A user viewing the alert or the alert dashboard may then determine to examine those features further. In some embodiments, the system or the user may, based on the set of discrepancy scores, choose to deploy the updated model instead of Machine Learning Model 112. For example, the system may take a sum of all discrepancy scores, or it may tally the number of nonzero discrepancy scores to compare against a preset number. The user may also decide to deploy the updated model instead of Machine Learning Model 112.

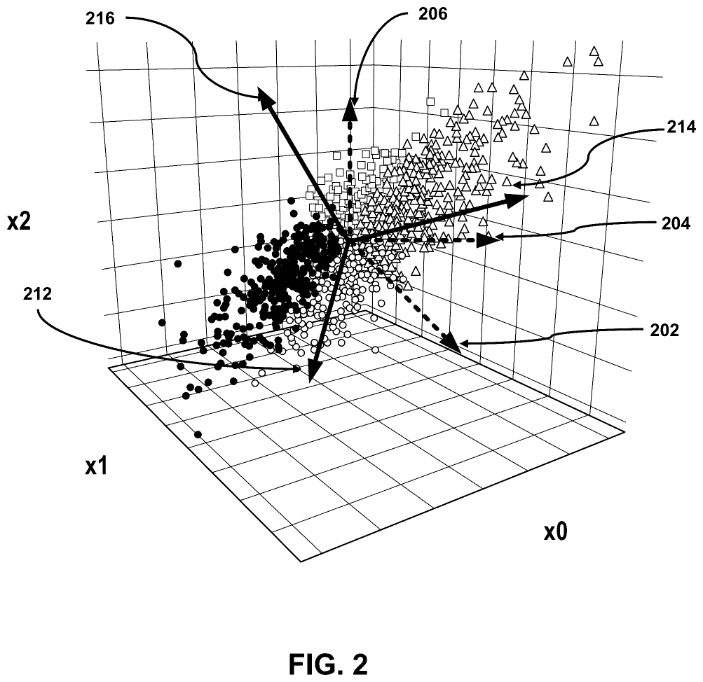

FIG. 2 is a demonstration of a first set of features and a second set of features. The first set of features may, in this example, contain three axes represented by three unit vectors: 202, 204 and 206. They are also labeled x0, x1 and x2 on FIG. 2. A user profile described by the first set of features may be represented as a vector of three real values, corresponding respectively to unit vector 202, unit vector 204 and unit vector 206. In some embodiments, user profiles thus described may be processed by Machine Learning Model 112.

Using, for example, the methods described above, this first set of features may give rise to a second set of features. The second set of features, in this example, is also three-dimensional. Unit vector 212, unit vector 214 and unit vector 216 represent the axes defining the three features. A user profiles with the second set of features is described by real values along these three dimensions. The second set of features may be the result of a recombination of unit vector 202, unit vector 204 and unit vector 206. The same user profile may be described by a set of real values for the first set of features and a different set of real values for the second set of features. An encoding map may be used to translate values for the first set of features into the second set of features. For example, an encoding map may take a user profile vector for the first set of features [2.3, 4, 9], corresponding to unit vector 202, 204 and 206. The encoding map may contain a list of weights [2, 10, 12] which may be applied to onto the user profile vector to produce a vector with values [4.6, 40, 108]. This vector encapsulates the user profile in the second set of features.

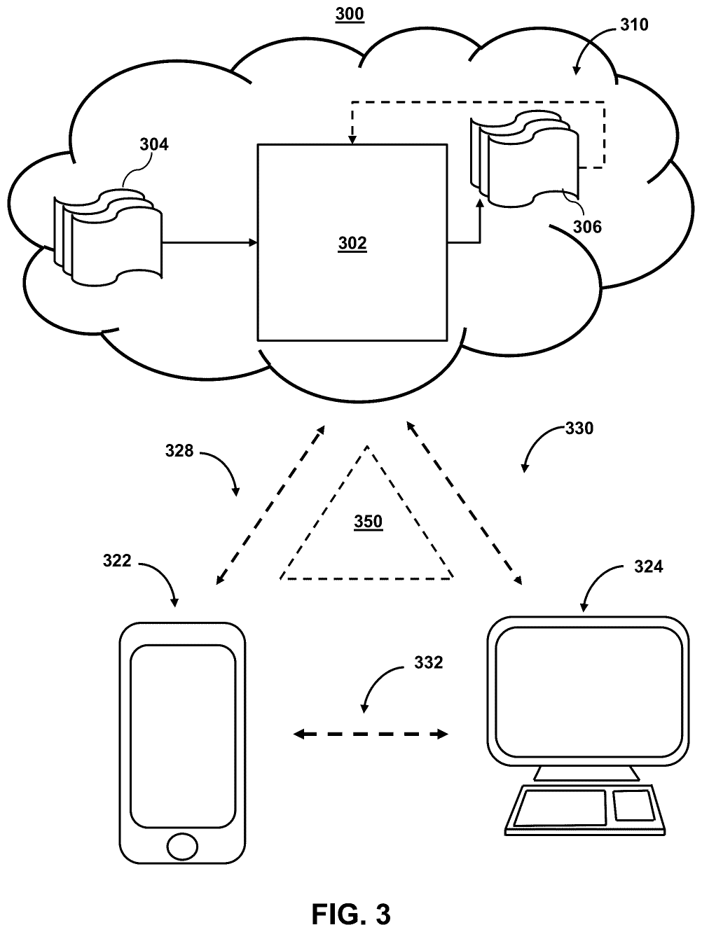

FIG. 3 shows illustrative components for a system used to communicate between the system and user devices and collect data, in accordance with one or more embodiments. As shown in FIG. 3, system 300 may include mobile device 322 and user terminal 324. While shown as a smartphone and personal computer, respectively, in FIG. 3, it should be noted that mobile device 322 and user terminal 324 may be any computing device, including, but not limited to, a laptop computer, a tablet computer, a hand-held computer, and other computer equipment (e.g., a server), including “smart,” wireless, wearable, and/or mobile devices. FIG. 3 also includes cloud components 310. Cloud components 310 may alternatively be any computing device as described above, and may include any type of mobile terminal, fixed terminal, or other device. For example, cloud components 310 may be implemented as a cloud computing system and may feature one or more component devices. It should also be noted that system 300 is not limited to three devices. Users may, for instance, utilize one or more devices to interact with one another, one or more servers, or other components of system 300. It should be noted, that, while one or more operations are described herein as being performed by particular components of system 300, these operations may, in some embodiments, be performed by other components of system 300. As an example, while one or more operations are described herein as being performed by components of mobile device 322, these operations may, in some embodiments, be performed by components of cloud components 310. In some embodiments, the various computers and systems described herein may include one or more computing devices that are programmed to perform the described functions. Additionally, or alternatively, multiple users may interact with system 300 and/or one or more components of system 300. For example, in one embodiment, a first user and a second user may interact with system 300 using two different components.

With respect to the components of mobile device 322, user terminal 324, and cloud components 310, each of these devices may receive content and data via input/output (hereinafter “I/O”) paths. Each of these devices may also include processors and/or control circuitry to send and receive commands, requests, and other suitable data using the I/O paths. The control circuitry may comprise any suitable processing, storage, and/or input/output circuitry. Each of these devices may also include a user input interface and/or user output interface (e.g., a display) for use in receiving and displaying data. For example, as shown in FIG. 3, both mobile device 322 and user terminal 324 include a display upon which to display data (e.g., conversational response, queries, and/or notifications).

Additionally, as mobile device 322 and user terminal 324 are shown as touchscreen smartphones, these displays also act as user input interfaces. It should be noted that in some embodiments, the devices may have neither user input interfaces nor displays and may instead receive and display content using another device (e.g., a dedicated display device such as a computer screen, and/or a dedicated input device such as a remote control, mouse, voice input, etc.). Additionally, the devices in system 300 may run an application (or another suitable program). The application may cause the processors and/or control circuitry to perform operations related to generating dynamic conversational replies, queries, and/or notifications.

Each of these devices may also include electronic storages. The electronic storages may include non-transitory storage media that electronically stores information. The electronic storage media of the electronic storages may include one or both of (i) system storage that is provided integrally (e.g., substantially non-removable) with servers or client devices, or (ii) removable storage that is removably connectable to the servers or client devices via, for example, a port (e.g., a USB port, a firewire port, etc.) or a drive (e.g., a disk drive, etc.). The electronic storages may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. The electronic storages may include one or more virtual storage resources (e.g., cloud storage, a virtual private network, and/or other virtual storage resources). The electronic storages may store software algorithms, information determined by the processors, information obtained from servers, information obtained from client devices, or other information that enables the functionality as described herein.

FIG. 3 also includes communication paths 328, 330, and 332. Communication paths 328, 330, and 332 may include the Internet, a mobile phone network, a mobile voice or data network (e.g., a 5G or LTE network), a cable network, a public switched telephone network, or other types of communications networks or combinations of communications networks. Communication paths 328, 330, and 332 may separately or together include one or more communications paths, such as a satellite path, a fiber-optic path, a cable path, a path that supports Internet communications (e.g., IPTV), free-space connections (e.g., for broadcast or other wireless signals), or any other suitable wired or wireless communications path or combination of such paths. The computing devices may include additional communication paths linking a plurality of hardware, software, and/or firmware components operating together. For example, the computing devices may be implemented by a cloud of computing platforms operating together as the computing devices.

Cloud components 310 may include model 302, which may be a machine learning model, artificial intelligence model, etc. (which may be referred collectively as “models” herein). Model 302 may take inputs 304 and provide outputs 306. The inputs may include multiple datasets, such as a training dataset and a test dataset. Each of the plurality of datasets (e.g., inputs 304) may include data subsets related to user data, predicted forecasts and/or errors, and/or actual forecasts and/or errors. In some embodiments, outputs 306 may be fed back to model 302 as input to train model 302 (e.g., alone or in conjunction with user indications of the accuracy of outputs 306, labels associated with the inputs, or with other reference feedback information). For example, the system may receive a first labeled feature input, wherein the first labeled feature input is labeled with a known prediction for the first labeled feature input. The system may then train the first machine learning model to classify the first labeled feature input with the known prediction (e.g., predicting resource allocation values for user systems).

In a variety of embodiments, model 302 may update its configurations (e.g., weights, biases, or other parameters) based on the assessment of its prediction (e.g., outputs 306) and reference feedback information (e.g., user indication of accuracy, reference labels, or other information). In a variety of embodiments, where model 302 is a neural network, connection weights may be adjusted to reconcile differences between the neural network's prediction and reference feedback. In a further use case, one or more neurons (or nodes) of the neural network may require that their respective errors are sent backward through the neural network to facilitate the update process (e.g., backpropagation of error). Updates to the connection weights may, for example, be reflective of the magnitude of error propagated backward after a forward pass has been completed. In this way, for example, the model 302 may be trained to generate better predictions.

In some embodiments, model 302 may include an artificial neural network. In such embodiments, model 302 may include an input layer and one or more hidden layers. Each neural unit of model 302 may be connected with many other neural units of model 302. Such connections can be enforcing or inhibitory in their effect on the activation state of connected neural units. In some embodiments, each individual neural unit may have a summation function that combines the values of all of its inputs. In some embodiments, each connection (or the neural unit itself) may have a threshold function such that the signal must surpass it before it propagates to other neural units. Model 302 may be self-learning and trained, rather than explicitly programmed, and can perform significantly better in certain areas of problem solving, as compared to traditional computer programs. During training, an output layer of model 302 may correspond to a classification of model 302, and an input known to correspond to that classification may be input into an input layer of model 302 during training. During testing, an input without a known classification may be input into the input layer, and a determined classification may be output.

In some embodiments, model 302 may include multiple layers (e.g., where a signal path traverses from front layers to back layers). In some embodiments, back propagation techniques may be utilized by model 302 where forward stimulation is used to reset weights on the “front” neural units. In some embodiments, stimulation and inhibition for model 302 may be more free-flowing, with connections interacting in a more chaotic and complex fashion. During testing, an output layer of model 302 may indicate whether or not a given input corresponds to a classification of model 302 (e.g., predicting resource allocation values for user systems).

In some embodiments, the model (e.g., model 302) may automatically perform actions based on outputs 306. In some embodiments, the model (e.g., model 302) may not perform any actions. The output of the model (e.g., model 302) may be used to predict predicting resource allocation values for user systems).

System 300 also includes API layer 350. API layer 350 may allow the system to generate summaries across different devices. In some embodiments, API layer 350 may be implemented on mobile device 322 or user terminal 324. Alternatively or additionally, API layer 350 may reside on one or more of cloud components 310. API layer 350 (which may be A REST or Web services API layer) may provide a decoupled interface to data and/or functionality of one or more applications. API layer 350 may provide a common, language-agnostic way of interacting with an application. Web services APIs offer a well-defined contract, called WSDL, that describes the services in terms of its operations and the data types used to exchange information. REST APIs do not typically have this contract; instead, they are documented with client libraries for most common languages, including Ruby, Java, PHP, and JavaScript. SOAP Web services have traditionally been adopted in the enterprise for publishing internal services, as well as for exchanging information with partners in B2B transactions.

API layer 350 may use various architectural arrangements. For example, system 300 may be partially based on API layer 350, such that there is strong adoption of SOAP and RESTful Web-services, using resources like Service Repository and Developer Portal, but with low governance, standardization, and separation of concerns. Alternatively, system 300 may be fully based on API layer 350, such that separation of concerns between layers like API layer 350, services, and applications are in place.

In some embodiments, the system architecture may use a microservice approach. Such systems may use two types of layers: Front-End Layer and Back-End Layer where microservices reside. In this kind of architecture, the role of the API layer 350 may provide integration between Front-End and Back-End. In such cases, API layer 350 may use RESTful APIs (exposition to front-end or even communication between microservices). API layer 350 may use AMQP (e.g., Kafka, RabbitMQ, etc.). API layer 350 may use incipient usage of new communications protocols such as gRPC, Thrift, etc.

In some embodiments, the system architecture may use an open API approach. In such cases, API layer 350 may use commercial or open-source API Platforms and their modules. API layer 350 may use a developer portal. API layer 350 may use strong security constraints applying WAF and DDOS protection, and API layer 350 may use RESTful APIs as standard for external integration.

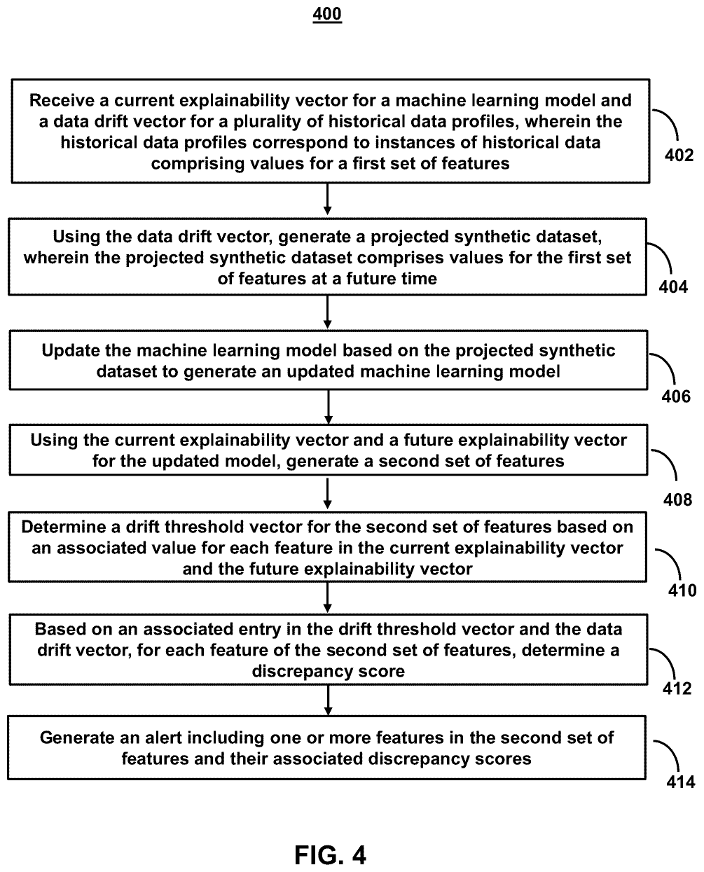

FIG. 4 shows a flowchart of the steps involved in forecasting data drift for model monitoring, in accordance with one or more embodiments. For example, the system may use process 400 (e.g., as implemented on one or more system components described above) in order to train models, create synthetic data, extract explainability vectors, and detect data drift for comparison.

At step 402, process 400 (e.g., using one or more components described above) may receive a current explainability vector for a machine learning model and a data drift vector for a plurality of historical data profiles. The machine learning model is trained on historical data, which correspond to the historical data profiles. The historical data comprises values for a first set of features. The first set of features may contain categorical or quantitative variables, and values for such features may describe, for example for models predicting resource availability values, the user system's make and model, the user system's location, the membership of the user system in any networks, any allocations of resources to the user system, a length of time for which the user system has recorded resource consumption, an extent and frequency of resource consumption, and the number of instances of the user system's excessive resource consumption. Each user profile may correspond to a resource availability value indicating the current amount of resources that should be made available to or reserved for the user system, which may also be recorded in the historical data in association with the user profile. The system may retrieve a plurality of user profiles as a matrix including vectors of feature values for the first set of features and append to the end of each vector a resource consumption value.

In some embodiments, the system may, after retrieving the historical data, process it using a data cleansing process to generate a processed dataset. The data cleansing process may include standardizing data types, formatting and units of measurement, and removing duplicate data. The system may then retrieve vectors corresponding to user profiles from the processed dataset.

In some embodiments, the historical data may correspond to a plurality of historical data profiles generated from the historical data. A data profile describing a dataset within the historical data (e.g., including a first set of features) may include descriptive statistics regarding the dataset. For example, the data profile may include a vector of averages across the first set of features in the dataset. For example, the data profile may include distributions of the first set of features in the dataset. For example, the data profile may include a list of frequencies of null values for the first set of features. For example, the data profile may include a covariance matrix between the first set of features.

A machine learning model (e.g., Machine Learning Model 112) may be trained on the historical data to perform prediction and/or classification using the first set of features as input. It may use algorithms such as neural networks, linear regression, Bayesian regression, and/or K-nearest neighbors to process the first set of features into an output. The system may partition the matrix of user profiles into a training set and a cross-validating set. Using the training set, the system may train Machine Learning Model 112 using, for example, the gradient descent technique. The system may then cross-validate the trained model using the cross-validating set and further fine-tune the parameters of the model. Machine Learning Model 112 may include one or more parameters that it uses to translate input into outputs. For example, an artificial neural network contains a matrix of weights, each weight in which is a real number. The repeated multiplication and combination of weights transform input values to Machine Learning Model 112 into output values.

The system may use Explainability Subsystem 114 to extract an explainability vector (e.g., Current Explainability Vector 134) from Machine Learning Model 112. Explainability Subsystem 114 may employ a variety of explainability techniques depending on the algorithms in Machine Learning Model 112 to extract Current Explainability Vector 134. Current Explainability Vector 134 contains one entry for each feature in the set of features in the input to Machine Learning Model 112, and the entry reflects the importance of that feature to the model. The values within Current Explainability Vector 134 additionally represent how each feature correlates to the output of the model, and the causative effect of each feature in producing the output as construed by the model. In some embodiments, a correlation matrix may be attached to Current Explainability Vector 134. The correlation matrix captures how variables are correlated with other variables. This is relevant because correlation between variables in a model causes interference in their causative effects in producing the output of the model.

Based on the historical data and/or the historical data profiles, the system may generate a data drift vector (e.g., Data Drift Vector 132). In some embodiments, the system may process the historical data and/or its corresponding data profiles using an extrapolation model to generate a data drift vector. Data Drift Vector 132 may be a vector of real values, each value corresponding to a feature in the first set of features. Each value within Data Drift Vector 132 may indicate an expected change to the average of the feature. In some embodiments, the entries in Data Drift Vector 132 may correspond to features in data profiles. In some embodiments, the data drift vector may include an expectation value and a measure of variance. The expectation value may be a vector of real values corresponding to the first set of features and the plurality of data profiles. The measure of variance may be a vector of real values, where each value is derived from a standard deviation of a feature in the set of features. Therefore, Data Drift Vector 132 may capture the expected values and expected variances for some or all of the features in the first set of features independently.

To generate the expectation value and the measure of variance, the system may use extrapolation machine learning models. For example, a time-series extrapolation machine learning model may use algorithms like Bayesian regression, time-series regression and/or principal component analysis. The extrapolation machine learning models may take the historical data profiles as input and may output predicted values for a set of features, each predicted value corresponding to a range of error. Thus, the system may use the predicted values to generate Data Drift Vector 132 by comparing the predicted values against the historical data.

At step 404, process 400 (e.g., using one or more components described above) may, using the data drift vector, generate a projected synthetic dataset, wherein the projected synthetic dataset comprises values for the first set of features at a future time. The system may generate a projected synthetic dataset using the data drift vector. For example, the system may use a first regression model to process the data drift vector and the historical data to generate projected values for the first set of features. In some embodiments, the data drift vector includes a set of values indicating projected expectations for the first set of features. In other embodiments, the system may calculate projected expectations for the first set of features using Data Drift Vector 132. For example, if Data Drift Vector 132 indicates an expected 10% in the mean of a feature and a 20% reduction in the variance of that feature, the system may generate projected expectations including expected mean values that are 0.9 times the current mean values, and expected variance that are 0.8 times the current variance. The system may generate the projected synthetic dataset using the projected expectations. For example, the system may simulate a statistical distribution with mean values equal to projected expectations and variance equal to projected variation. Using the statistical distribution, the system may generate values for the first set of features, which may be collected to form a projected synthetic dataset.

At step 406, process 400 (e.g., using one or more components described above) may update the machine learning model based on the projected synthetic dataset to generate an updated machine learning model. The system may update Machine Learning Model 112 based on the projected synthetic dataset. Machine Learning Model 112 may be retrained on the projected synthetic dataset to perform prediction and/or classification, again using the first set of features as input. It may use the same algorithms as before, such as neural networks, linear regression, Bayesian regression, and/or K-nearest neighbors, to process the first set of features into an output. The system may partition the projected synthetic dataset into a training set and a cross-validating set. Using the training set, the system may train Machine Learning Model 112 using, for example, the gradient descent technique. The system may then cross-validate the trained model using the cross-validating set and further fine-tune the parameters of the model. Despite using the same set of features, the updated model may have a different set of weights and other parameters than Machine Learning Model 112, because it was trained on the projected synthetic dataset. Consequently, the importance of each feature may be different from its importance in Machine Learning Model 112.

At step 408, process 400 (e.g., using one or more components described above) may, using the current explainability vector and a future explainability vector for the updated model, generate a second set of features. The system may then process the updated machine learning model to extract a future explainability vector (e.g., Future Explainability Vector 136). The system may again use Explainability Subsystem 114, which may employ a variety of explainability techniques depending on the algorithms in the updated model. Future Explainability Vector 136 contains one entry for each feature in the set of features in the input to the updated model, and the entry reflects the importance of that feature to the updated model. The values within Future Explainability Vector 136 additionally represent how each feature correlates to the output of the updated model, and the causative effect of each feature in producing the output as construed by the updated model. Future Explainability Vector 136 may be of the same format as Current Explainability Vector 134 described above.

The system may choose a second set of features based on Current Explainability Vector 134 and Future Explainability Vector 136. Feature Extraction Subsystem 116 may, for example, calculate a threshold for including features in the second set based on the explainability vector. In some embodiments, the threshold may correspond to a pre-set real number, e.g., 0.45. In other embodiments, Feature Extraction Subsystem 116 may simply select the top 10% of features ranked by values in the explainability vector. Using the threshold, Feature Extraction Subsystem 116 may add features to the second of features. In some embodiments Feature Extraction Subsystem 116 may combine features with reference to Current Explainability Vector 134. For example, it may select features with low values in Current Explainability Vector 134 and map one or more such features into one combined feature. Feature Extraction Subsystem 116 may, for example, multiply the absolute values for three features to generate one new feature. Alternatively, Feature Extraction Subsystem 116 may determine whether all three feature values exceed thresholds for each and create a new feature which outputs 1 if all values are above their respect thresholds, and outputs 0 otherwise.

In some embodiments, Feature Extraction Subsystem 116 may employ a variety of techniques to rearrange or recombine the first set of features into the second set of features. For example, Feature Extraction Subsystem 116 may normalize Current Explainability Vector 134 into a standard-deviation space to produce a processed vector. Then, with reference to the correlation matrix attached to Current Explainability Vector 134, Feature Extraction Subsystem 116 may generate a covariance matrix based on the processed vector. The covariance matrix captures how the effects on the output of the model of one or more features correlate. Using the covariance matrix, Feature Extraction Subsystem 116 may compute a set of eigenvectors and eigenvalues for the covariance matrix (e.g., through the Singular Value Decomposition method). Each eigenvector corresponds to an eigenvalue and represents a feature in the first set of features. The relative proportions of the eigenvalues are directly correlated with the magnitude of a factor's explanative weight in Machine Learning Model 112. By normalizing the eigenvalues of all features in the first set of features, the system may determine what percentage of the explanative power of the model may be captured by each feature. Feature Extraction Subsystem 116 may then select a measure of coverage (e.g., a threshold percentage of the explanative power of the model). Using the measure of coverage, Feature Extraction Subsystem 116 may select a subset of eigenvectors from the set of eigenvectors. For example, if the measure of coverage is 55%, and three eigenvectors' eigenvalues add up to 56% when normalized, Feature Extraction Subsystem 116 may select the three eigenvectors. Feature Extraction Subsystem 116 may then determine the second set of features to correspond to the subset of eigenvectors.

At step 410, process 400 (e.g., using one or more components described above) may determine a drift threshold vector for the second set of features based on an associated value for each feature in the current explainability vector and the future explainability vector. The system may then determine a drift threshold vector (e.g., Drift Threshold Vector 118) for the second set of features. Drift Threshold Vector 118 may be inversely proportional to values in explainability vectors for each feature in the second set of features. For example, the system may initialize a uniform vector, where each value is the same real number. Then the system may calculate a weight vector, each value in which corresponds to a feature in the second set of features. For each feature in the second set of features, the feature has a value in Current Explainability Vector 134 and a value in Future Explainability Vector 136. The weight may be the higher of these two values. In some embodiments, the weight may be a mathematical combination of the two values, for example an average. The system determines values for Drift Threshold Vector 118 by dividing each value in the uniform vector by each value in the weight vector. The higher that a feature's values in Current Explainability Vector 134 and Future Explainability Vector 136 are, the lower its threshold in Drift Threshold Vector 118.

At step 412, process 400 (e.g., using one or more components described above) may, based on an associated entry in the drift threshold vector and the data drift vector, for each feature of the second set of features, determine a discrepancy score. For each feature of the second set of features, the system may determine a discrepancy score using the drift threshold vector and the data drift vector for each feature in the second set of features. The data drift vector may indicate an expected change to the mean for a feature. In some embodiments, the expected changes to the mean may be normalized to be a standard-deviation space. In some embodiments, the uniform vector used in generating the drift threshold vector may be selected to be in the same order of magnitude as the data drift vector. The system may compare values in the data drift vector for the second set of features against values in the drift threshold vector. For example, the system may compute a numerical difference in the real number in the data drift vector and the drift threshold vector for each feature and set the value as the discrepancy score for that feature.

At step 414, process 400 (e.g., using one or more components described above) may generate an alert including one or more features in the second set of features and their associated discrepancy scores. The system may generate an alert including one or more features in the second set of features and their associated discrepancy scores in the following manner. For example, some features in the second set of features may have positive discrepancy scores, indicating that the degree of drift exceeded the drift threshold for that feature. The system may select those features, and generate an alert (e.g., in an alert dashboard displayed to users) indicating those features and their discrepancy scores. A user viewing the alert or the alert dashboard may then determine to examine those features further. In some embodiments, the system or the user may, based on the set of discrepancy scores, choose to deploy the updated model instead of Machine Learning Mode 112. For example, the system may take a sum of all discrepancy scores, or it may tally the number of nonzero discrepancy scores to compare against a preset number. The user may also decide to deploy the updated model instead of Machine Learning Mode 112.

It is contemplated that the steps or descriptions of FIG. 4 may be used with any other embodiment of this disclosure. In addition, the steps and descriptions described in relation to FIG. 4 may be done in alternative orders or in parallel to further the purposes of this disclosure. For example, each of these steps may be performed in any order, in parallel, or simultaneously to reduce lag or increase the speed of the system or method. Furthermore, it should be noted that any of the components, devices, or equipment discussed in relation to the figures above could be used to perform one or more of the steps in FIG. 4.

The above-described embodiments of the present disclosure are presented for purposes of illustration and not of limitation, and the present disclosure is limited only by the claims which follow. Furthermore, it should be noted that the features and limitations described in any one embodiment may be applied to any embodiment herein, and flowcharts or examples relating to one embodiment may be combined with any other embodiment in a suitable manner, done in different orders, or done in parallel. In addition, the systems and methods described herein may be performed in real time. It should also be noted that the systems and/or methods described above may be applied to, or used in accordance with, other systems and/or methods.

The present techniques will be better understood with reference to the following enumerated embodiments:

1. A method for using historical data profiles, projected synthetic datasets and explainable artificial intelligence techniques to forecast data drift for model monitoring, comprising: receiving a machine learning model and a plurality of historical data profiles, wherein the machine learning model is trained on historical data, wherein the historical data profiles correspond to instances of the historical data at different times, and wherein the historical data comprises values for a first set of features; processing the machine learning model to extract a current explainability vector, wherein each entry in the current explainability vector corresponds to a feature in the first set of features and is indicative of a correlation between the feature and an output of the machine learning model; based on the plurality of historical data profiles, generating a data drift vector, wherein each entry in the data drift vector is indicative of expected change to a feature of the first set of features for the historical data; using the data drift vector, generating a projected synthetic dataset, wherein the projected synthetic dataset comprises values for the first set of features at a future time; updating the machine learning model based on the projected synthetic dataset to generate an updated machine learning model; processing the updated machine learning model to extract a future explainability vector, wherein each entry in the future explainability vector corresponds to a feature in the first set of features and is indicative of a correlation between the feature and an output of the updated machine learning model; using the current explainability vector and the future explainability vector, generating a second set of features including features with associated values in the current explainability vector or the future explainability vector above a threshold, wherein the second set of features is a subset of the first set of features; determining a drift threshold vector for the second set of features based on an associated value for each feature in the current explainability vector and the future explainability vector, wherein each entry in the drift threshold vector corresponds to a feature of the second set of features and is indicative of a degree of allowed drift for the feature; based on an associated entry in the drift threshold vector and the data drift vector, for each feature of the second set of features, determining a discrepancy score between the associated entry in the drift threshold vector and an associated entry in the data drift vector; and generating a notification dashboard, comprising an alert including one or more features in the second set of features and their associated discrepancy scores.
2. A method for using historical data profiles, projected synthetic datasets and explainable artificial intelligence techniques to forecast data drift for model monitoring, comprising: receiving a current explainability vector for a machine learning model and a data drift vector for a plurality of historical data profiles, wherein the machine learning model is trained on historical data, wherein the historical data profiles correspond to instances of the historical data at different times, and wherein the historical data comprises values for a first set of features; using the data drift vector, generating a projected synthetic dataset, wherein the projected synthetic dataset comprises values for the first set of features at a future time; updating the machine learning model based on the projected synthetic dataset to generate an updated machine learning model; using the current explainability vector and a future explainability vector for the updated machine learning model, generating a second set of features, wherein the second set of features is a subset of the first set of features; determining a drift threshold vector for the second set of features based on an associated value for each feature in the current explainability vector and the future explainability vector; based on an associated entry in the drift threshold vector and the data drift vector, for each feature of the second set of features, determining a discrepancy score between the associated entry in the drift threshold vector and an associated entry in the data drift vector; and generating an alert including one or more features in the second set of features and their associated discrepancy scores.
3. A method for using historical data profiles, projected synthetic datasets and explainable artificial intelligence techniques to forecast data drift for model monitoring, comprising: using a data drift vector for a plurality of historical data profiles, generating a projected synthetic dataset, wherein the projected synthetic dataset comprises values for a first set of features at a future time, wherein the plurality of historical data profiles correspond to instances of historical data at different times, and wherein the historical data comprises values for the first set of features; using a current explainability vector for a machine learning model trained on the historical data and a future explainability vector for an updated machine learning model generated from updating the machine learning model on the projected synthetic dataset, generating a second set of features; based on an associated entry in a drift threshold vector for the second set of features and the data drift vector, for each feature of the second set of features, determining a discrepancy score between the associated entry in the drift threshold vector and an associated entry in the data drift vector; and generating an alert including one or more features in the second set of features and their associated discrepancy scores.
4. The method of any one of the preceding embodiments, wherein generating the data drift vector comprises: using a time-series extrapolation model, processing the historical data and the plurality of historical data profiles to generate the data drift vector, wherein the data drift vector comprises magnitudes of change for first set of features.
5. The method of any one of the preceding embodiments, wherein determining the drift threshold vector for the second set of features comprises: generating a uniform vector, wherein the uniform vector comprises a real value repeated a number of times equal to a number of features in the second set of features; generating a weight vector, wherein the weight vector comprises the greater of an associated value in the current explainability vector and an associated value in the future explainability vector for each feature in the second set of features; and determining the drift threshold vector by dividing the uniform vector by the weight vector.
6. The method of any one of the preceding embodiments, wherein: the machine learning model is defined by a set of parameters comprising a matrix of weights for a multivariate regression algorithm; and the current explainability vector is extracted from the set of parameters using a Shapley Additive Explanation method.
7. The method of any one of the preceding embodiments, wherein: the machine learning model is defined by a set of parameters comprising a matrix of weights for a supervised classifier algorithm; and the current explainability vector is extracted from the set of parameters using a Local Interpretable Model-agnostic Explanations method.
8. The method of any one of the preceding embodiments, wherein: the machine learning model is defined by a set of parameters comprising a vector of coefficients for a generalized additive model; and the current explainability vector is extracted from the vector of coefficients in the generalized additive model.
9. The method of any one of the preceding embodiments, wherein: the machine learning model is defined by a set of parameters comprising a matrix of weights for a convolutional neural network algorithm; and the current explainability vector is extracted from the set of parameters using a Gradient Class Activation Mapping method.
10. The method of any one of the preceding embodiments, wherein: the machine learning model is defined by a set of parameters comprising a hyperplane matrix for a support vector machine algorithm; and the current explainability vector is extracted from the set of parameters using a counterfactual explanation method.
11. The method of any one of the preceding embodiments, further comprising: based on one or more discrepancy scores, determining to employ the updated machine learning model in place of the machine learning model.
12. The method of any one of the preceding embodiments, wherein generating the projected synthetic dataset using the data drift vector comprises: using a first regression model, processing the data drift vector and the historical data to generate projected values for the first set of features.
13. The method of any one of the preceding embodiments, wherein generating the second set of features comprises: generating a covariance matrix based on the current explainability vector and the future explainability vector; computing a set of eigenvectors for the covariance matrix; selecting a measure of coverage and selecting a subset of eigenvectors from the set of eigenvectors based on the measure of coverage; and determining the second set of features corresponding to the subset of eigenvectors.
14. One or more non-transitory computer-readable media storing instructions that, when executed by a data processing apparatus, cause the data processing apparatus to perform operations comprising those of any of embodiments 1-13.
15. A system comprising one or more processors; and memory storing instructions that, when executed by the processors, cause the processors to effectuate operations comprising those of any of embodiments 1-13.
16. A system comprising means for performing any of embodiments 1-13.

What is claimed is:

1. A system for using historical data profiles, projected synthetic datasets, and explainable artificial intelligence techniques to forecast data drift for model monitoring, comprising:
one or more processors;
one or more non-transitory computer-readable media comprising instructions that, when executed by the one or more processors, cause operations comprising:
receiving a machine learning model and a plurality of historical data profiles, wherein the machine learning model is trained on historical data, wherein the historical data profiles correspond to instances of the historical data at different times, and wherein the historical data comprises values for a first set of features;
processing the machine learning model to extract a current explainability vector, wherein each entry in the current explainability vector corresponds to a feature in the first set of features and is indicative of a correlation between the feature and an output of the machine learning model;
based on the plurality of historical data profiles, generating a data drift vector, wherein each entry in the data drift vector is indicative of expected change to a feature of the first set of features for the historical data;
using the data drift vector, generating a projected synthetic dataset, wherein the projected synthetic dataset comprises values for the first set of features at a future time;
updating the machine learning model based on the projected synthetic dataset to generate an updated machine learning model;
processing the updated machine learning model to extract a future explainability vector, wherein each entry in the future explainability vector corresponds to a feature in the first set of features and is indicative of a correlation between the feature and an output of the updated machine learning model;
using the current explainability vector and the future explainability vector, generating a second set of features including features with associated values in the current explainability vector or the future explainability vector above a threshold, wherein the second set of features is a subset of the first set of features;
determining a drift threshold vector for the second set of features based on an associated value for each feature in the current explainability vector and the future explainability vector, wherein each entry in the drift threshold vector corresponds to a feature of the second set of features and is indicative of a degree of allowed drift for the feature;
based on an associated entry in the drift threshold vector and the data drift vector, for each feature of the second set of features, determining a discrepancy score between the associated entry in the drift threshold vector and an associated entry in the data drift vector; and
generating a notification dashboard, comprising an alert including one or more features in the second set of features and their associated discrepancy scores.

2. A method for using historical data profiles, projected synthetic datasets, and explainable artificial intelligence techniques to forecast data drift for model monitoring, comprising:
receiving a current explainability vector for a machine learning model and a data drift vector for a plurality of historical data profiles, wherein the machine learning model is trained on historical data, wherein the historical data profiles correspond to instances of the historical data at different times, and wherein the historical data comprises values for a first set of features;
using the data drift vector, generating a projected synthetic dataset, wherein the projected synthetic dataset comprises values for the first set of features at a future time;
updating the machine learning model based on the projected synthetic dataset to generate an updated machine learning model;
using the current explainability vector and a future explainability vector for the updated machine learning model, generating a second set of features, wherein the second set of features is a subset of the first set of features;
determining a drift threshold vector for the second set of features based on an associated value for each feature in the current explainability vector and the future explainability vector;
based on an associated entry in the drift threshold vector and the data drift vector, for each feature of the second set of features, determining a discrepancy score between the associated entry in the drift threshold vector and an associated entry in the data drift vector; and
generating an alert including one or more features in the second set of features and their associated discrepancy scores.

3. The method of claim 2, wherein generating the data drift vector comprises:
using a time-series extrapolation model, processing the historical data and the plurality of historical data profiles to generate the data drift vector, wherein the data drift vector comprises magnitudes of change for first set of features.

4. The method of claim 3, wherein determining the drift threshold vector for the second set of features comprises:
generating a uniform vector, wherein the uniform vector comprises a real value repeated a number of times equal to a number of features in the second set of features;
generating a weight vector, wherein the weight vector comprises the greater of an associated value in the current explainability vector and an associated value in the future explainability vector for each feature in the second set of features; and
determining the drift threshold vector by dividing the uniform vector by the weight vector.

5. The method of claim 2, wherein:
the machine learning model is defined by a set of parameters comprising a matrix of weights for a multivariate regression algorithm; and
the current explainability vector is extracted from the set of parameters using a Shapley Additive Explanation method.

6. The method of claim 2, wherein:
the machine learning model is defined by a set of parameters comprising a matrix of weights for a supervised classifier algorithm; and
the current explainability vector is extracted from the set of parameters using a Local Interpretable Model-agnostic Explanations method.

7. The method of claim 2, wherein:
the machine learning model is defined by a set of parameters comprising a vector of coefficients for a generalized additive model; and
the current explainability vector is extracted from the vector of coefficients in the generalized additive model.

8. The method of claim 2, wherein:
the machine learning model is defined by a set of parameters comprising a matrix of weights for a convolutional neural network algorithm; and
the current explainability vector is extracted from the set of parameters using a Gradient Class Activation Mapping method.

9. The method of claim 2, wherein:
the machine learning model is defined by a set of parameters comprising a hyperplane matrix for a support vector machine algorithm; and
the current explainability vector is extracted from the set of parameters using a counterfactual explanation method.

10. The method of claim 2, further comprising:
based on one or more discrepancy scores, determining to employ the updated machine learning model in place of the machine learning model.

11. The method of claim 2, wherein generating the projected synthetic dataset using the data drift vector comprises:
using a first regression model, processing the data drift vector and the historical data to generate projected values for the first set of features.

12. The method of claim 2, wherein generating the second set of features comprises:
generating a covariance matrix based on the current explainability vector and the future explainability vector;
computing a set of eigenvectors for the covariance matrix;
selecting a measure of coverage and selecting a subset of eigenvectors from the set of eigenvectors based on the measure of coverage; and
determining the second set of features corresponding to the subset of eigenvectors.

13. One or more non-transitory computer-readable media comprising instructions that, when executed by one or more processors, cause operations comprising:
using a data drift vector for a plurality of historical data profiles, generating a projected synthetic dataset, wherein the projected synthetic dataset comprises values for a first set of features at a future time, wherein the plurality of historical data profiles correspond to instances of historical data at different times, and wherein the historical data comprises values for the first set of features;
using a current explainability vector for a machine learning model trained on the historical data and a future explainability vector for an updated machine learning model generated from updating the machine learning model on the projected synthetic dataset, generating a second set of features;
based on an associated entry in a drift threshold vector for the second set of features and the data drift vector, for each feature of the second set of features, determining a discrepancy score between the associated entry in the drift threshold vector and an associated entry in the data drift vector; and
generating an alert including one or more features in the second set of features and their associated discrepancy scores.

14. The one or more non-transitory computer-readable media of claim 13, wherein generating the data drift vector comprises:
using a time-series extrapolation model, processing the historical data and the plurality of historical data profiles to generate the data drift vector, wherein the data drift vector comprises magnitudes of change for first set of features.

15. The one or more non-transitory computer-readable media of claim 14, wherein determining the drift threshold vector for the second set of features comprises:
generating a uniform vector, wherein the uniform vector comprises a real value repeated a number of times equal to a number of features in the second set of features;
generating a weight vector, wherein the weight vector comprises the greater of an associated value in the current explainability vector and an associated value in the future explainability vector for each feature in the second set of features; and
determining the drift threshold vector by dividing the uniform vector by the weight vector.

16. The one or more non-transitory computer-readable media of claim 13, wherein:
the machine learning model is defined by a set of parameters comprising a matrix of weights for a multivariate regression algorithm; and
the current explainability vector is extracted from the set of parameters using a Shapley Additive Explanation method.

17. The one or more non-transitory computer-readable media of claim 13, wherein:
the machine learning model is defined by a set of parameters comprising a matrix of weights for a supervised classifier algorithm; and
the current explainability vector is extracted from the set of parameters using a Local Interpretable Model-agnostic Explanations method.

18. The one or more non-transitory computer-readable media of claim 13, further comprising:
based on one or more discrepancy scores, determining to employ the updated machine learning model in place of the machine learning model.

19. The one or more non-transitory computer-readable media of claim 13, wherein generating the projected synthetic dataset using the data drift vector comprises:
using a first regression model, processing the data drift vector and the historical data to generate projected values for the first set of features.

20. The one or more non-transitory computer-readable media of claim 13, wherein generating the second set of features comprises:
generating a covariance matrix based on the current explainability vector and the future explainability vector;
computing a set of eigenvectors for the covariance matrix;
selecting a measure of coverage and selecting a subset of eigenvectors from the set of eigenvectors based on the measure of coverage; and
determining the second set of features corresponding to the subset of eigenvectors.
